(19) United States
(12) Patent Application Publication
(10) Pub. No.: US 2021/0336193 A1
(43) Pub. Date: Oct. 28, 2021

(54) MIRROR ORGANIC LIGHT-EMITTING DIODE DEVICE AND METHOD OF MANUFACTURING SAME

(71) Applicant: Shenzhen China Star Optoelectronics Semiconductor Display Technology Co., Ltd., Shenzhen, Guangdong (CN)

(72) Inventors: Wei TAN, Shenzhen, Guangdong (CN); Aiguo TU, Shenzhen, Guangdong (CN)

(21) Appl. No.: 16/613,162

(22) PCT Filed: Aug. 28, 2019
(86) PCT No.: PCT/CN2019/103101

§ 371 Date: Nov. 13, 2019

(30) Foreign Application Priority Data
Jun. 20, 2019 (CN) 201910535872.0

(51) Int. Cl. H01L 51/52; H01L 51/00; H01L 27/32

(52) U.S. Cl. CPC H01L 51/5234; H01L 51/0011; H01L 51/56; H01L 51/5246; H01L 27/3244

(57) ABSTRACT

The disclosure provides a mirror (organic light-emitting diode) OLED device and a method of manufacturing same. A transparent cathode and a reflective cathode on an organic layer are made of two different material. The reflective cathode and the transparent cathode are disposed alternately. A periphery of the reflective cathode and a periphery of the transparent cathode are connected to each other, thereby improving conductivity of the entire cathode. A mirror OLED display device manufactured by the method has both a display function and a reflective function which will not interfere with each other. A flexible, large-scale mirror OLED display device with various shapes is realized.

### FIELD

The present disclosure relates to the field of display and, more particularly, relates to a mirror organic light-emitting diode device and a method of manufacturing same.

### BACKGROUND

With rapid development of display technology, a variety of novel technologies keep growing. Display devices with multiple functions have been one of a goal that people desire to achieve. Currently, mirror display devices are widely used in markets because they can simultaneously realize a display function and a mirror function. Mirror display technology (e.g., public advertising display panels, automotive rearview mirrors, and ATM screens) means that a display device can not only be used as a mirror but can display images, which satisfies people's various requirements.

Regarding technical problems: In traditional technology, display devices with a display function and a mirror function can be classified into two types, namely, semi-transmissive semi-reflective display devices and plug-in display devices. The semi-transmissive semi-reflective display devices have a disadvantage that its display panel will display images on transmissive area and display area at the same time if an ambient brightness is too high, which reduces sharpnesses of the display images. Display panel and mirror of the plug-in display devices are disposed separately, which is difficult to manufacture and is not easy to realize a flexible display device with various shapes.

### SUMMARY

To overcome the shortcomings of the traditional technology, the present disclosure provides a mirror organic light-emitting diode (OLED) display device and a method of manufacturing same. A transparent cathode and a reflective cathode are disposed on an organic layer individually when the OLED is manufactured. Two peripheries of the reflective cathode are respectively connected to peripheries of two transparent cathodes, thereby improving conductivity of the entire cathode. A display function and a reflective function of the mirror OLED display device provided by the present disclosure will not interfere with each other, furthermore, the manufacturing process is simple, which can realize a flexible and large-scale mirror display device with various shapes.

Technical solutions provided by the present disclosure are as follows:

The present disclosure provides a mirror organic light-emitting diode (OLED) display device, including: a thin film transistor (TFT) substrate including a plurality of light-emitting pixels; an anode disposed on the TFT substrate; an organic layer disposed on the anode; at least one transparent cathode disposed on a region of the organic layer corresponding to the light-emitting pixels; and at least one reflective cathode disposed on a region of the organic layer outside the region of the organic layer corresponding to the light-emitting pixels.

In at least one embodiment provided by the present disclosure, the reflective cathode and the transparent cathode are disposed alternately.

In at least one embodiment provided by the present disclosure, a periphery of the reflective cathode and a periphery of the transparent cathode are connected to each other.

In at least one embodiment provided by the present disclosure, material of the transparent cathode is at least one of Mg or Ag.

In at least one embodiment provided by the present disclosure, material of the reflective cathode is at least one of Al or Ag.

In at least one embodiment provided by the present disclosure, an encapsulating structure of the encapsulation layer is flexible encapsulation or plate encapsulation.

In at least one embodiment provided by the present disclosure, the organic layer further includes: a hole injection layer disposed on the anode; a hole transport layer disposed on the hole injection layer; a luminescent layer disposed on a region of the hole transport layer corresponding to the light-emitting pixels; an electron transport layer disposed on the luminescent layer; and an electron injection layer disposed on the electron transport layer.

The present disclosure further provides a method of manufacturing an organic light-emitting diode (OLED) display device, including the following steps:

step 1: forming a plurality of light-emitting pixels on a thin film transistor (TFT) substrate.

step 2: sequentially forming an anode and an organic layer on the TFT substrate.

step 3: forming a transparent cathode on a region of the organic layer corresponding to the light-emitting pixels.

step 4: forming a reflective cathode on a region of the organic layer outside the region of the organic layer corresponding to the light-emitting pixels.

step 5: encapsulating the TFT substrate.

In at least one embodiment provided by the present disclosure, the reflective cathode and the transparent cathode are disposed alternately.

In at least one embodiment provided by the present disclosure, a periphery of the reflective cathode and a periphery of the transparent cathode are connected to each other.

In at least one embodiment provided by the present disclosure, material of the transparent cathode is at least one of Mg or Ag.

In at least one embodiment provided by the present disclosure, material of the reflective cathode is at least one of Al or Ag.

In at least one embodiment provided by the present disclosure, the transparent cathode is formed by a fine metal mask.

In at least one embodiment provided by the present disclosure, the reflective cathode is formed by a fine metal mask.

In at least one embodiment provided by the present disclosure, an encapsulating structure of the encapsulation layer is flexible encapsulation or plate encapsulation.

In at least one embodiment provided by the present disclosure, a step of manufacturing the organic layer of the step 2 further includes:

step 21: depositing a hole injection layer on the anode.

step 22: depositing a hole transport layer on the hole injection layer.

step 23: depositing a luminescent layer on a region of the hole transport layer corresponding to the light-emitting pixels.

step 24: depositing an electron transport layer on the luminescent layer.

step 25: depositing an electron injection layer on the electron transport layer.

Regarding the beneficial effects: The mirror OLED display device manufactured by a method provided by the present disclosure is made by normal OLED manufacturing process. Different from traditional technology, the transparent cathode and the reflective cathode of the mirror OLED display device provided by the present disclosure are respectively disposed on a region of the organic layer corresponding to the light-emitting pixels and a region of the organic layer outside the region of the organic layer corresponding to the light-emitting pixels. The reflective cathode and the transparent cathode are disposed alternately. The periphery of the reflective cathode and the periphery of the transparent cathode are connected to each other, thereby improving conductivity of the entire cathode. A display function and a reflective function of the mirror OLED display device provided by the present disclosure will not interfere with each other, furthermore, the manufacturing process is simple, which can realize a flexible and large-scale mirror OLED display device with various shapes.

### DESCRIPTION OF DRAWINGS

The accompanying figures to be used in the description of embodiments of the present disclosure or prior art will be described in brief to more clearly illustrate the technical solutions of the embodiments or the prior art. Apparently, the accompanying figures described below are only part of the embodiments of the present disclosure, from which figures those skilled in the art can derive further figures without making any inventive efforts.

FIG. 1 is a schematic view showing a layered structure of a mirror OLED display device according to a first embodiment of the present disclosure.

FIG. 2 is a top view of the mirror OLED display device according to the first embodiment of the present disclosure.

FIG. 3 is a flowchart showing steps of manufacturing a mirror OLED display device according to a second embodiment of the present disclosure.

FIG. 4 is a top view of the mirror OLED display device after step 1 according to the second embodiment of the present disclosure.

FIG. 5 is a flowchart showing steps of manufacturing an organic layer of step 2 according to the second embodiment of the present disclosure.

FIG. 6 is a schematic view showing a layered structure of the mirror OLED display device after step 2 according to the second embodiment of the present disclosure.

FIG. 7 is a schematic view showing a layered structure of the mirror OLED display device after step 3 according to the second embodiment of the present disclosure.

FIG. 8 is a schematic view showing a layered structure of the mirror OLED display device after step 4 according to the second embodiment of the present disclosure.

FIG. 9 is a schematic view showing a layered structure of the mirror OLED display device after step 5 according to the second embodiment of the present disclosure.

### DETAILED DESCRIPTION

The following description of the various embodiments is provided with reference to the accompanying drawings. It should be understood that terms such as “upper”, “lower”, “front”, “rear”, “left”, “right”, “inside”, “outside”, “clockwise”, “lateral”, as well as derivative thereof should be construed to refer to the orientation as then described or as shown in the drawings under discussion. These relative terms are for convenience of description, do not require that the present disclosure be constructed or operated in a particular orientation, and shall not be construed as causing limitations to the present disclosure. In the drawings, the identical or similar reference numerals constantly denote the identical or similar elements or elements having the identical or similar functions.

In traditional mirror OLED display device, a display function and a reflective function of the mirror OLED display device will interfere with each other, furthermore, a plug-in mirror display device is difficult to realize a flexible and large-scale mirror display device with various shapes, the following embodiments can solve the above technical problems.

To more clearly illustrate the present disclosure, in a first embodiment and a second embodiment, a region of a TFT substrate corresponding to light-emitting pixels is defined as a luminescent region A1, and a region of the TFT substrate outside the luminescent region A1 is defined as a reflective region A2.

### First Embodiment

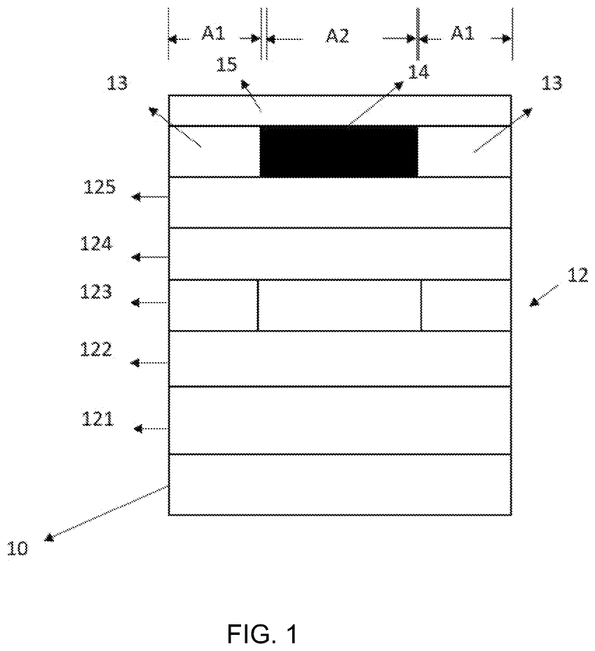

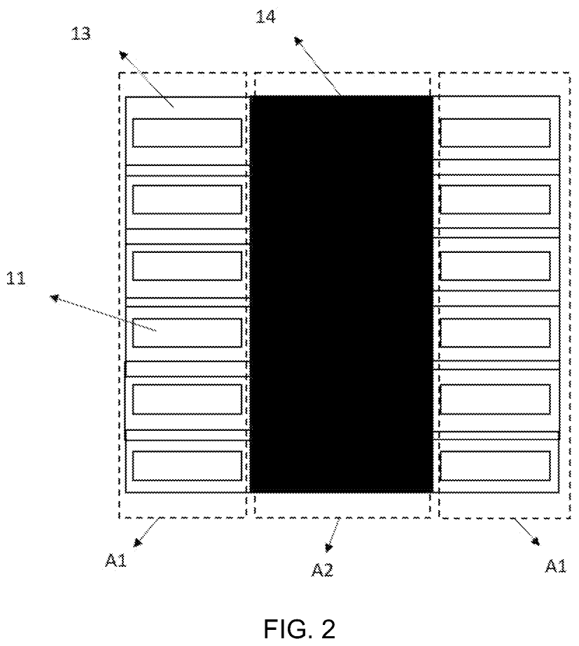

As shown in FIG. 1 and FIG. 2, the present embodiment provides an mirror OLED display device, including a thin film transistor (TFT) substrate 10 including a plurality of light-emitting pixels 11; an anode (not shown) disposed on the TFT substrate 10; an organic layer 12 disposed on the anode; two transparent cathodes 13 disposed on the organic layer 12 and in the luminescent region A1; a reflective cathode 14 disposed on the organic layer 12 and in the reflective region A2.

Specifically, as shown in FIG. 1, the organic layer 12 may further include a hole injection layer 121, a hole transport layer 122, a luminescent layer 123, an electron transport layer 124, and an electron injection layer 125. The luminescent layer 123 is only deposited on the hole transport layer 122 and in the luminescent region A1.

Specifically, the reflective cathode 14 and the transparent cathode 13 are disposed alternately, and a periphery of the reflective cathode 14 and a periphery of the transparent cathode 13 are connected to each other. Therefore, conductivity of the entire cathode is improved, and a display function and a reflective function of the mirror OLED display device will not interfere with each other.

Specifically, material of the transparent cathode 13 is at least one of transparent conductive metal material such as Mg, Al, or other transparent metal oxides.

Specifically, material of the reflective cathode 14 is at least one of high-reflectivity conductive metal material such as Al or Ag.

Specifically, the mirror OLED display device further include an encapsulation layer 15 disposed on the transparent cathode 13 and the reflective cathode 14. In the present embodiment, an encapsulating structure of the encapsulation layer 15 may be flexible encapsulation or plate encapsulation.

Specifically, in the mirror OLED display device of the present embodiment, material of the transparent cathode 13 and that of the reflective cathode 14 are different. The reflective cathode 14 and the transparent cathode 13 are disposed alternately, and a periphery of the reflective cathode 14 and a periphery of the transparent cathode 13 are connected to each other. Therefore, conductivity of the entire cathode is improved, and a display function and a reflective function of the mirror OLED display device will not interfere with each other. A high-quality mirror OLED display device with both a display function and a reflective function can be realized.

### Second Embodiment

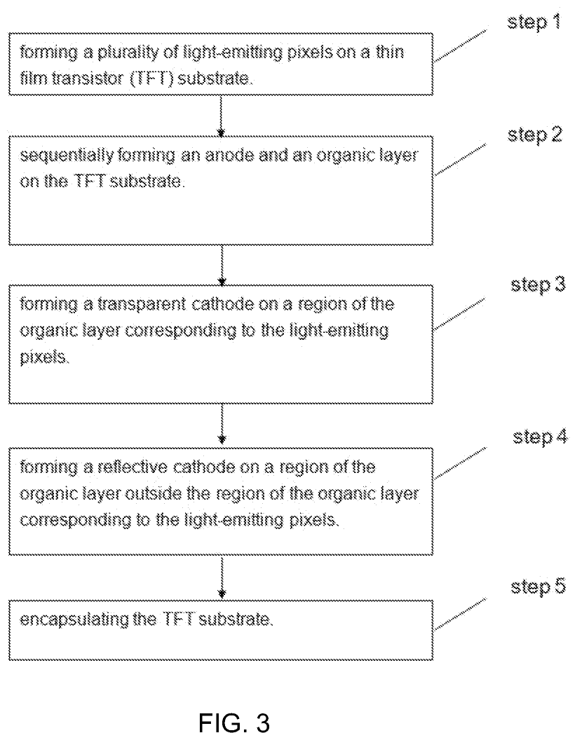

As shown in FIG. 3, the present disclosure provides a method of manufacturing a mirror OLED display device, including the following steps:

step 1: forming a plurality of light-emitting pixels on a thin film transistor (TFT) substrate.

step 2: sequentially forming an anode and an organic layer on the TFT substrate.

step 3: forming a transparent cathode on a region of the organic layer corresponding to the light-emitting pixels.

step 4: forming a reflective cathode on a region of the organic layer outside the region of the organic layer corresponding to the light-emitting pixels.

step 5: encapsulating the TFT substrate.

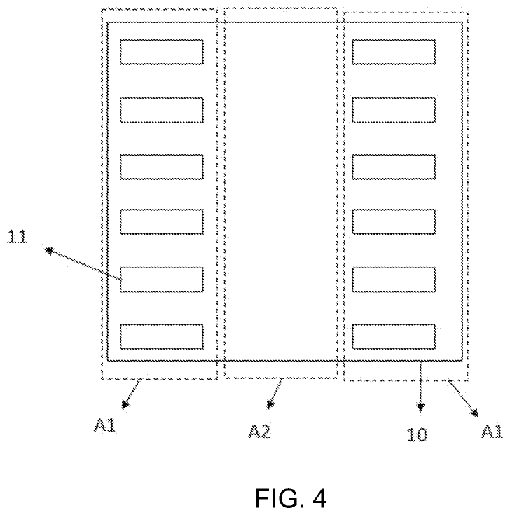

Specifically, as shown in FIG. 4, after the plurality of light-emitting pixels 11 are formed on the TFT substrate 10. A region of the TFT substrate 10 corresponding to the light-emitting pixels 11 is defined as the luminescent region A1 which is a light-emitting region of the mirror OLED display device manufactured by a method provided by the present disclosure. A region of the TFT substrate 10 outside the luminescent region A1 is the reflective region A2 which is a reflective region of the mirror OLED display device manufactured by the method provided by the present disclosure.

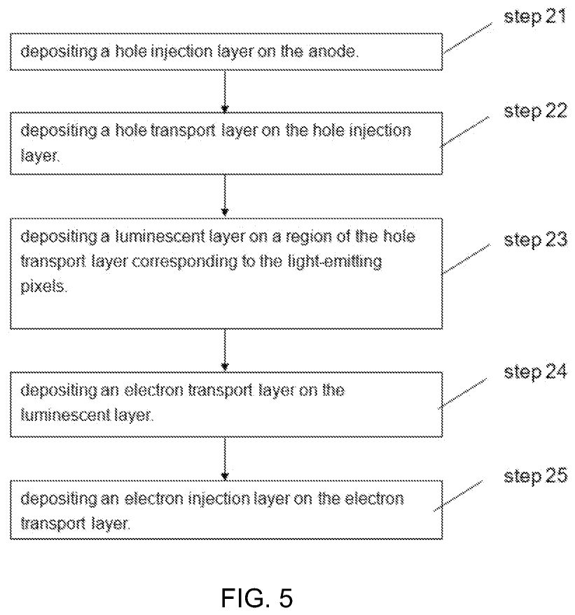

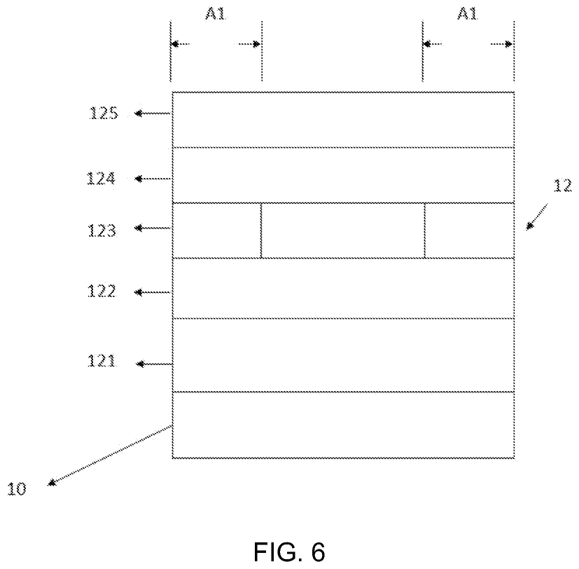

Specifically, as shown in FIG. 5 and FIG. 6, a step of manufacturing the organic layer in the step 2 further includes:

step 21: depositing a hole injection layer on the anode.

step 22: depositing a hole transport layer on the hole injection layer.

step 23: depositing a luminescent layer on the hole transport layer and in the luminescent region A1.

step 24: depositing an electron transport layer on the luminescent layer.

step 25: depositing an electron injection layer on the electron transport layer.

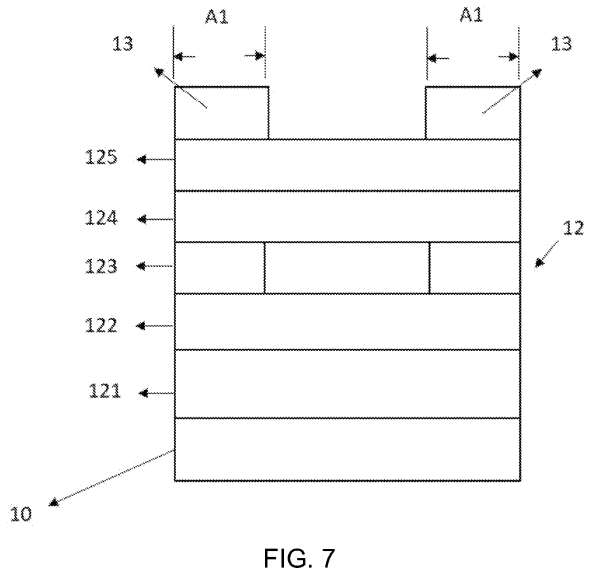

Specifically, the step 3 is shown in FIG. 7, the transparent cathode 13 is disposed on the organic layer 12 and in the luminescent region A1. Material of the transparent cathode 13 is at least one of transparent conductive metal material such as Mg, Al, or other transparent metal oxides. As a result, light can be transmitted through the luminescent region A1 to realize a display function.

Specifically, the transparent cathode 13 is formed by a fine metal mask (FMM). The FMM is a metal plate with millions of holes which are used to precisely control deposition position of vapor deposition and ensure that the transparent cathode 13 is only deposited on the organic layer 12 and in the luminescent region A1. As a result, a mirror OLED display device with both a display function and a reflective function can be realized, wherein the display function and the reflective function will not interfere with each other.

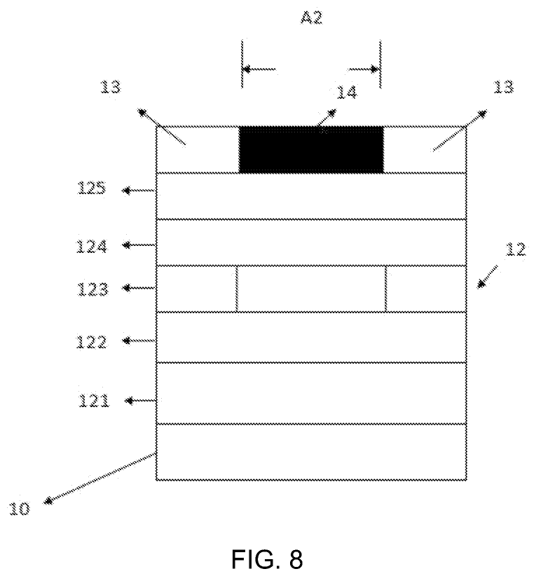

Specifically, the step 4 is shown in FIG. 8, the reflective cathode 14 is disposed on the organic layer 12 and in the reflective region A2. Material of the reflective cathode 14 is at least one of transparent conductive metal material such as Al or Ag. As a result, the reflective region A2 can reflect light.

Specifically, the reflective cathode 14 is formed by a FMM. The FMM is a metal plate with millions of holes which are used to precisely control deposition position of vapor deposition and ensure that the reflective cathode 14 is only deposited on the organic layer 12 and in the reflective region A2. As a result, a mirror OLED display device with both a display function and a reflective function can be realized, wherein the display function and the reflective function will not interfere with each other.

Specifically, the reflective cathode 14 and the transparent cathode 13 are disposed alternately, and a periphery of the reflective cathode 14 and a periphery of the transparent cathode 13 are connected to each other. Therefore, conductivity of the entire cathode is improved, and a display function and a reflective function of the mirror OLED display device will not interfere with each other.

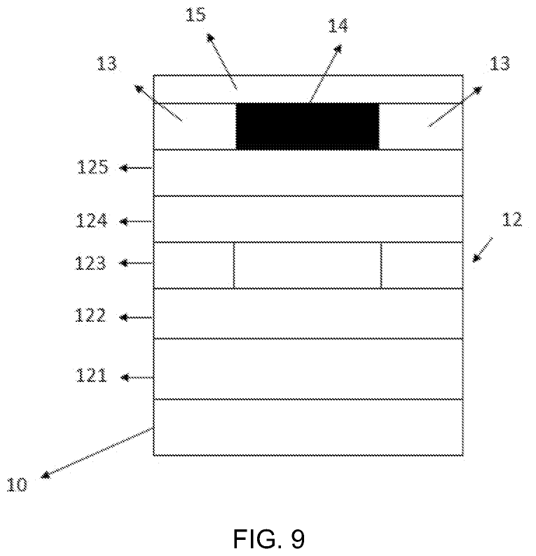

Specifically, encapsulating method in the step 5 may be flexible encapsulation, plate encapsulation, or other encapsulating structures. An encapsulated structured is shown in FIG. 9. An encapsulation layer 15 is deposited on the transparent cathode 13 and the reflective cathode 14.

Regarding the beneficial effects: In the method of manufacturing a mirror OLED display device, the transparent cathode and the reflective cathode of the mirror OLED display device are respectively disposed on a region of the organic layer corresponding to light-emitting pixels and a region of the organic layer outside the region of the organic layer corresponding to the light-emitting pixels. The reflective cathode and the transparent cathode are disposed alternately. The periphery of the reflective cathode and the periphery of the transparent cathode are connected to each other, thereby improving conductivity of the entire cathode. A display function and a reflective function of the mirror OLED display device provided by the present disclosure will not interfere with each other, further, the manufacturing process is simple, which can realize a flexible and large-scale mirror OLED display device with various shapes.

The present disclosure has been described with a preferred embodiment thereof. The preferred embodiment is not intended to limit the present disclosure, and it is understood that many changes and modifications to the described embodiment can be carried out without departing from the scope and the spirit of the disclosure that is intended to be limited only by the appended claims.

What is claimed is:

1. A mirror organic light-emitting diode (OLED) display device, comprising:
a thin film transistor (TFT) substrate comprising a plurality of light-emitting pixels;
an anode disposed on the TFT substrate;
an organic layer disposed on the anode;
at least one transparent cathode disposed on a region of the organic layer corresponding to the light-emitting pixels;
at least one reflective cathode disposed on a region of the organic layer outside the region of the organic layer corresponding to the light-emitting pixels; and
an encapsulation layer disposed on the transparent cathode and the reflective cathode.

2. The mirror OLED display device of claim 1, wherein the reflective cathode and the transparent cathode are disposed alternately.

3. The mirror OLED display device of claim 2, wherein a periphery of the reflective cathode and a periphery of the transparent cathode are connected to each other.

4. The mirror OLED display device of claim 1, wherein material of the transparent cathode is at least one of Mg or Ag.

5. The mirror OLED display device of claim 1, wherein material of the reflective cathode is at least one of Al or Ag.

6. The mirror OLED display device of claim 1, wherein an encapsulating structure of the encapsulation layer is flexible encapsulation or plate encapsulation.

7. The mirror OLED display device of claim 1, wherein the organic layer further comprises:
a hole injection layer disposed on the anode;
a hole transport layer disposed on the hole injection layer;
a luminescent layer disposed on a region of the hole transport layer corresponding to the light-emitting pixels;
an electron transport layer disposed on the luminescent layer; and
an electron injection layer disposed on the electron transport layer.

8. A method of manufacturing an organic light-emitting diode (OLED) display device, comprising the following steps:
step 1: forming a plurality of light-emitting pixels on a thin film transistor (TFT) substrate;
step 2: sequentially forming an anode and an organic layer on the TFT substrate;
step 3: forming a transparent cathode on a region of the organic layer corresponding to the light-emitting pixels;
step 4: forming a reflective cathode on a region of the organic layer outside the region of the organic layer corresponding to the light-emitting pixels; and
step 5: encapsulating the TFT substrate.

9. The method of claim 8, wherein the reflective cathode and the transparent cathode are disposed alternately.

10. The method of claim 9, wherein a periphery of the reflective cathode and a periphery of the transparent cathode are connected to each other.

11. The method of claim 8, wherein material of the transparent cathode is at least one of Mg or Ag.

12. The method of claim 8, wherein material of the reflective cathode is at least one of Al or Ag.

13. The method of claim 8, wherein the transparent cathode is formed by a fine metal mask.

14. The method of claim 8, wherein the reflective cathode is formed by a fine metal mask.

15. The method of claim 8, wherein an encapsulating structure of the encapsulation layer is flexible encapsulation or plate encapsulation.

16. The method of claim 8, wherein a step of manufacturing the organic layer of the step 2 further includes:
step 21: depositing a hole injection layer on the anode;
step 22: depositing a hole transport layer on the hole injection layer;
step 23: depositing a luminescent layer on a region of the hole transport layer corresponding to the light-emitting pixels;
step 24: depositing an electron transport layer on the luminescent layer; and
step 25: depositing an electron injection layer on the electron transport layer.
